(19) United States
(12) Patent Application Publication
(10) Pub. No.: US 2009/0305153 A1
(43) Pub. Date: Dec. 10, 2009

(54) SUBSTRATE PROCESSING METHOD AND MASK MANUFACTURING METHOD

(76) Inventors: Hideaki Sakurai, Kanagawa-ken (JP); Yukio Oppata, Chiba-ken (JP); Masamitsu Itoh, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/479,202

(22) Filed: Jun. 5, 2009

(30) Foreign Application Priority Data
Jun. 6, 2008 (JP) 2008-148940

(51) Int. Cl. G03F 7/20; B08B 3/04; B08B 7/04

(52) U.S. Cl. 430/30; 134/21; 134/18; 430/320

(57) ABSTRACT

A substrate processing method uses a processing fluid to selectively process only a region of a portion of a processing surface of a substrate to be processed, by causing a discharge aperture and a suction aperture of a nozzle having the discharge aperture and the suction aperture for the processing fluid and provided movable relative to the substrate to be processed to face the processing surface of the substrate and suctioning the processing fluid supplied onto the processing surface through the suction aperture while supplying the processing fluid from the discharge aperture onto the processing surface.

### CROSS-REFERENCE TO RELATED APPLICATIONS

This application is based upon and claims the benefit of priority from the prior Japanese Patent Application No. 2008-148940, filed on Jun. 6, 2008; the entire contents of which are incorporated herein by reference.

### BACKGROUND OF THE INVENTION

1. Field of the Invention

The present invention relates to a substrate processing method and a mask manufacturing method used for the manufacture of a semiconductor device, a liquid crystal display, and the like.

2. Background Art

Various processing is performed in a semiconductor manufacturing process such as cleaning, developing, and the like. However, conventional cleaning processing and developing processing is performed by supplying a cleaning fluid and a developing fluid to the entire processing surface of a substrate. For example, in JP-A 2005-26512 (Kokai), a nozzle extending longer in one direction is scanned in a direction orthogonal to the longitudinal direction to supply the developing fluid to the entire processing surface.

With the miniaturization of semiconductor devices in recent years, challenging levels of precision including pattern dimensions of several nanometers are required, and the need is therefore stronger for substrate processing with higher processing precision.

### SUMMARY OF THE INVENTION

According to an aspect of the invention, there is provided a substrate processing method that uses a processing fluid to selectively process only a region of a portion of a processing surface of a substrate to be processed, by causing a discharge aperture and a suction aperture of a nozzle having the discharge aperture and the suction aperture for the processing fluid and provided movable relative to the substrate to be processed to face the processing surface of the substrate and suctioning the processing fluid supplied onto the processing surface through the suction aperture while supplying the processing fluid from the discharge aperture onto the processing surface.

According to another aspect of the invention, there is provided a mask manufacturing method including: forming a pattern on a mask substrate; and using a cleaning fluid to selectively clean only a region of a portion of a pattern formation surface of the mask substrate, by causing a discharge aperture and a suction aperture of a nozzle having the discharge aperture and the suction aperture for the cleaning fluid and provided movable relative to the mask substrate to face the pattern formation surface of the mask substrate and suctioning the cleaning fluid supplied onto the pattern formation surface through the suction aperture while supplying the cleaning fluid from the discharge aperture onto the pattern formation surface.

According to still another aspect of the invention, there is provided a mask manufacturing method including: forming a latent image of a pattern on a resist formed on a mask substrate; developing a latent image formed in a region of a portion of the resist to form a resist sensitivity measurement pattern, by causing a discharge aperture and a suction aperture of a nozzle having the discharge aperture and the suction aperture for a developing fluid and provided movable relative to the mask substrate to face the resist and suctioning the developing fluid supplied onto the region of the portion of the resist through the suction aperture while supplying the developing fluid from the discharge aperture onto the resist; determining a developing condition from resist sensitivity information obtained during the developing of the resist sensitivity measurement pattern; and developing a latent image formed on the resist in a region different than the region in which the resist sensitivity measurement pattern is formed based on the developing condition to form a main pattern.

### BRIEF DESCRIPTION OF THE DRAWINGS

FIG. 1 is a flowchart illustrating main processes of a substrate processing method according to a first embodiment of the invention;

FIG. 2 is a schematic view showing an example of a particle distribution on a mask substrate in the first embodiment of the invention;

FIG. 3 is a schematic view showing an example of a possible cleaning number distribution on the mask substrate in the first embodiment of the invention;

FIG. 4A is a graphic view showing the relationship between the transmittance in the mask surface and the cleaning time, and FIG. 4B is a graphic view showing the relationship between the phase difference in the mask surface and the cleaning time;

FIG. 5 is a schematic view of a nozzle used for the substrate processing according to embodiments of the invention;

FIG. 6 is a schematic view of a nozzle lower surface of the nozzle facing a processing surface;

FIG. 7 is a schematic view for describing a selective cleaning on the mask substrate in the first embodiment of the invention;

FIG. 8 is a schematic view showing another specific example of the nozzle used for the substrate processing according to the embodiment of the invention;

FIG. 9 is a flowchart illustrating main processes of a substrate processing method according to a second embodiment of the invention;

FIG. 10 is a schematic view for describing a selective cleaning on the mask substrate in the second embodiment of the invention;

FIG. 11 is a schematic view illustrating the relationship between the developing time and the pattern dimension;

FIGS. 12A to 12D are schematic views showing main processes of a substrate processing method according to a third embodiment of the invention;

FIG. 13 is a schematic view of an air nozzle available for a particle removal in the third embodiment of the invention;

FIGS. 14A to 14C are schematic views for describing a selective processing of the substrate according to a fourth embodiment of the invention;

FIGS. 15A to 15C are schematic views showing an apparatus configuration used for a selective processing of the substrate according to a fifth embodiment of the invention;

FIG. 16 is a schematic view illustrating the relationship between the reflectance of a monitor pattern (resist thickness) and the developing time according to the fifth embodiment of the invention; and

FIG. 17 is a block diagram for describing the flow of a feedback process of reflectance measurement results in the fifth embodiment of the invention.

### DETAILED DESCRIPTION OF THE INVENTION

Embodiments of the present invention will now be described with reference to the drawings.

### First Embodiment

This embodiment illustrates a cleaning processing as an example of a substrate processing method. Although the cleaning processing is repeatedly performed during semiconductor manufacturing processes, this embodiment particularly illustrates the cleaning processing of mask manufacturing steps as an example.

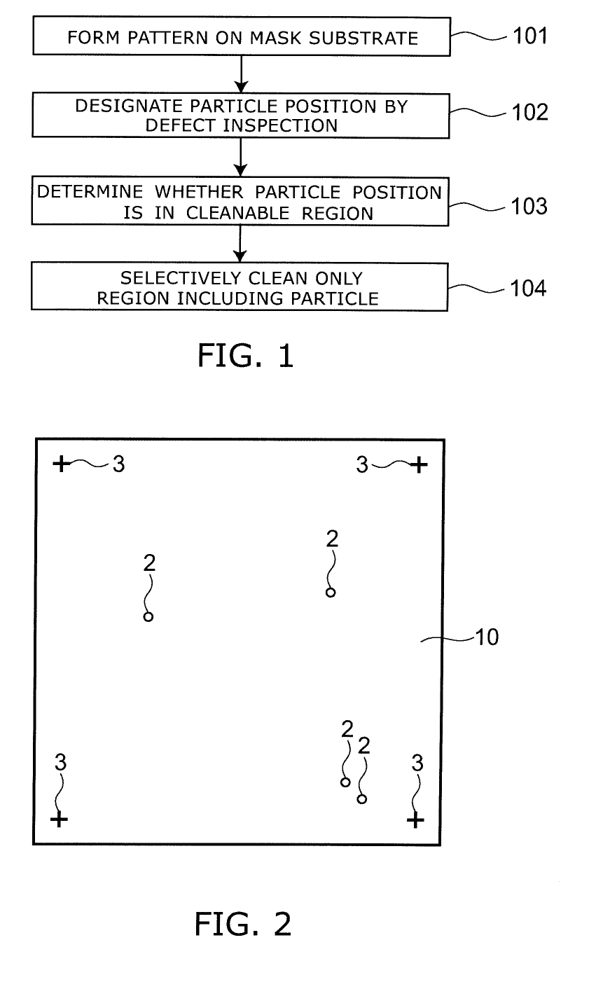

FIG. 1 is a flowchart illustrating main processes of the mask manufacturing including a cleaning method according to this embodiment.

First, in step 101, a desired pattern is formed on a mask substrate by sequentially performing processing such as, for example, applying a resist on the mask substrate including a light shielding film and/or a semi-transparent film on a glass substrate; exposing the resist (for example, by electron-beam lithography); performing PEB (Post Exposure Baking); developing the resist; etching the light shielding film and/or the semi-transparent film using the resist as a mask; and resist removal.

Then, in step 102, a defect inspection of the pattern formation surface of the mask substrate is performed; and in the case where a defect exists, the position thereof is designated. The defect inspection herein performs an inspection of whether or not a fine contamination particle (hereinbelow also referred to as “particle”) that affects masking optical characteristics is adhered on the pattern formation surface. In the case where a particle is detected, the particle is considered to be an object to be removed from the pattern formation surface, and a processing is performed to wash away and remove the particle in a cleaning process described below.

In the case where a particle is found by the inspection recited above, the position thereof is designated. FIG. 2 illustrates a pattern formation surface that is a surface to be cleaned (processing surface) of a mask substrate 10. For example, in the case where particles 2 are found at the illustrated positions, the positions of the particles 2 are designated by ascertaining the relative coordinates of the particles 2 with respect to pattern marks 3 formed at four corners of the pattern formation surface (at positions outside of a formation region of a main pattern actually transferred onto a semiconductor wafer) as a reference.

Generally, in the cleaning process, energy is physically or chemically applied to the substrate surface to remove the particle adhered to the mask substrate. Therefore, damage of the substrate surface (the light shielding film and/or the semi-transparent film) occurs. Also, performing the cleaning processing causes changes in the transmittance and/or the phase difference in the mask surface.

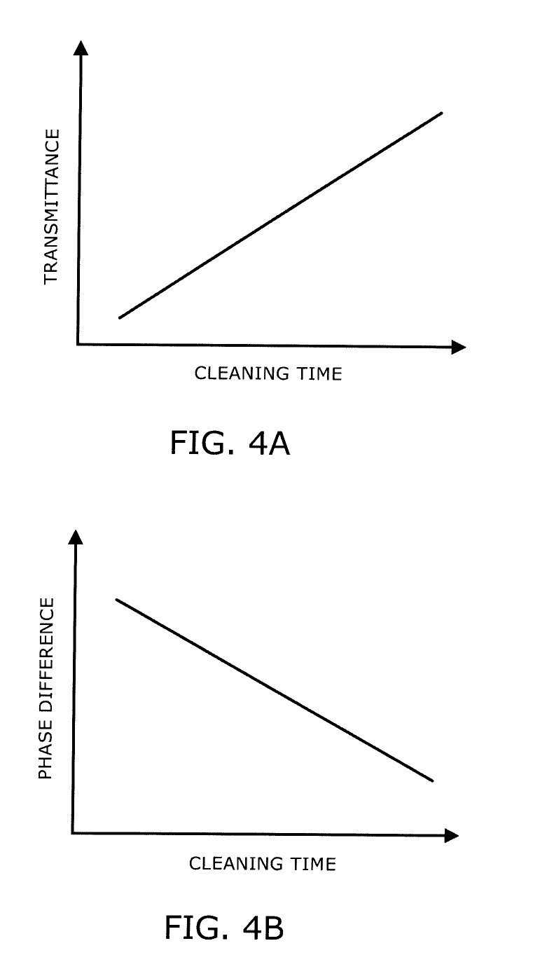

As illustrated in FIG. 4A, the transmittance tends to increase as the cleaning time (number of cleanings) increases. As illustrated in FIG. 4B, the phase difference tends to decrease as the cleaning time (number of cleanings) increases.

Accordingly, in the case where cleaning processing is repeated several times, it is no longer possible to satisfy the required mask specifications due to changes of the transmittance and/or the phase difference of the film. Therefore, the number of cleanings may be limited. The permissible number of cleanings is not the same over the entire pattern formation surface. The distribution of the permissible number of cleanings is determined according to the distribution of the pattern (film).

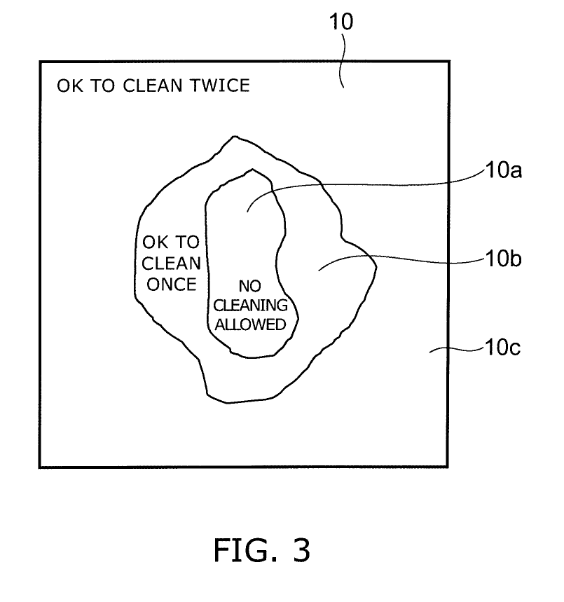

In this embodiment, change amount data of the transmittance, phase difference, configuration, and the like of the film per cleaning is acquired in advance. A map (distribution) of the number of possible cleanings for the mask is ascertained based on the change amount data to obtain the desired lithographical margins (exposure amount margin, focus margin, etc.). An example of a possible cleaning number distribution is illustrated in FIG. 3.

For example, a region 10a, in which not even one cleaning is permissible, exists in a central portion of the pattern formation surface of the mask substrate 10. On the outside thereof, a region 10b exists in which one cleaning is permissible. The other region on the outside thereof is a region 10c in which two cleanings are permissible.

In the next step, the previously obtained positions of the particles 2 (the relative coordinates with respect to the pattern marks 3) and the possible cleaning number distribution are compared; and it is determined whether or not the positions of the particles 2 are in the cleanable region (step 103 in FIG. 1).

In the case where a position of a particle 2 is in the cleanable region, that is, in the case where the particle 2 is positioned in a region having at least one permissible cleaning, only the region including the particle 2 is selectively cleaned (step 104). After at least one cleaning is performed, in the case where the cleaning processing is once again performed, the determination of step 103 determines whether or not a position of the particle 2 is in a region having at least one possible cleaning remaining.

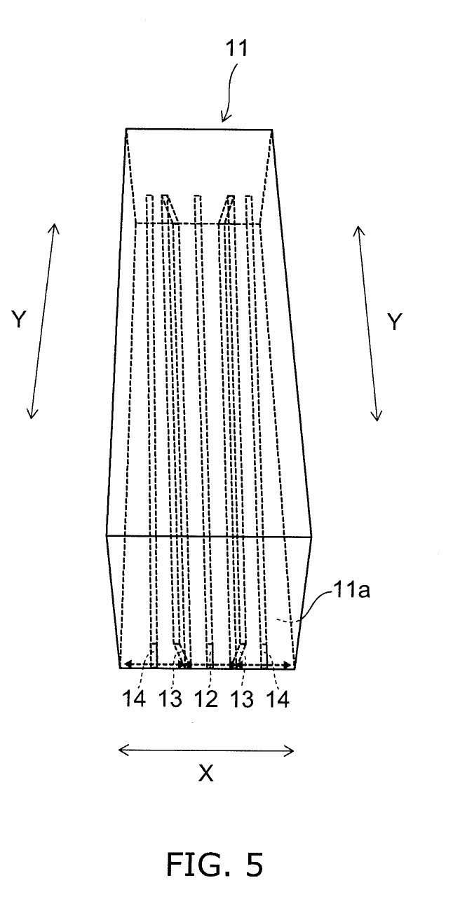

In the example illustrated in FIG. 7, each particle 2 is in a region having at least one possible cleaning. In this embodiment, a nozzle 11 illustrated in FIG. 5 is used to perform a selective cleaning processing to remove the particles 2.

The nozzle 11 is formed in a rectangular parallelepiped configuration in which two main directions (an X direction and a Y direction) are prescribed. The Y direction is the longitudinal direction of the nozzle 11. The X direction is orthogonal to the Y direction and indicates the movement direction of the nozzle 11 with respect to the mask substrate.

An interior of the nozzle 11 is provided with a discharge path 12 and suction paths 13 of a cleaning fluid and discharge paths 14 of a rinsing fluid. Each path is made in a slit configuration extending in the longitudinal direction (Y direction) of the nozzle 11.

The discharge path 12, the suction paths 13, and the discharge paths 14 are provided in line in the X direction recited above. One discharge path 12 is positioned at nearly the center in the X direction. A pair of suction paths 13 is positioned on either side of the discharge path 12. A pair of discharge paths 14 is positioned on either side of the pair of suction paths 13.

The discharge path 12 and the discharge paths 14 are substantially perpendicular to a nozzle lower face 11a, while the suction paths 13 incline gradually inward toward the discharge path 12 from a nozzle upper face side toward the nozzle lower face 11a.

The discharge path 12, the suction paths 13, and the discharge paths 14 open at the nozzle lower face 11a and communicate to the nozzle exterior as a discharge aperture 12a, suction apertures 13a, and discharge apertures 14a, respectively.

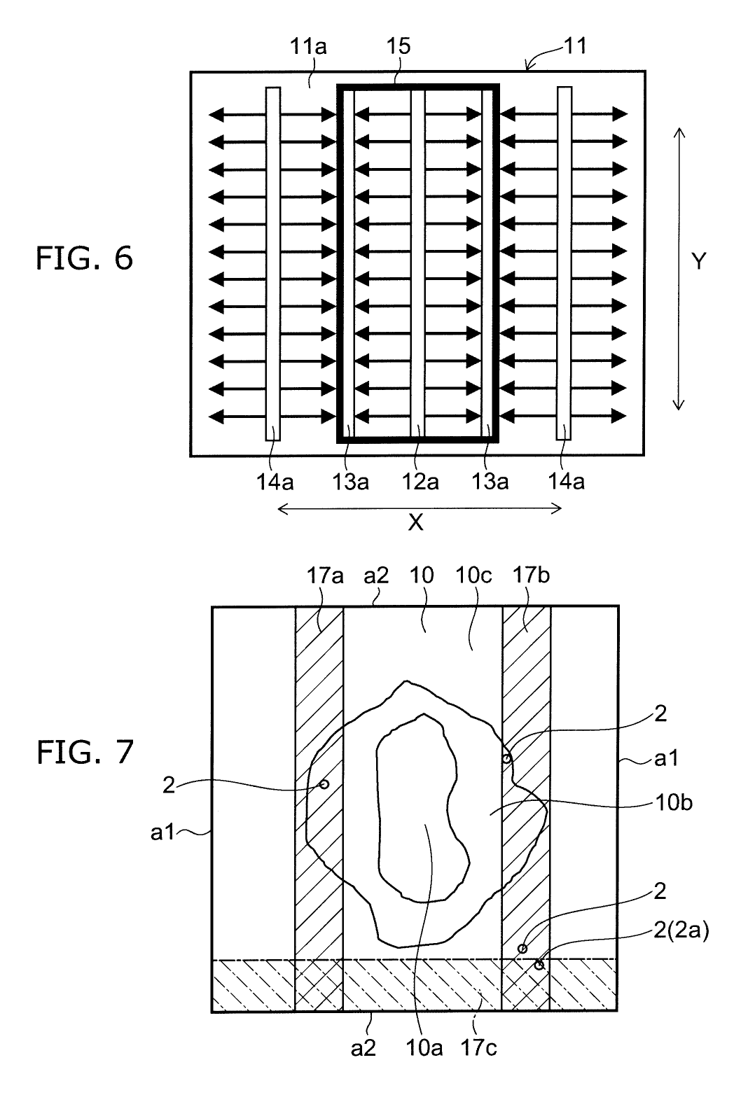

FIG. 6 is a schematic view illustrating an arrangement of the discharge aperture 12a and the suction apertures 13a of the cleaning fluid and the discharge apertures 14a of the rinsing fluid at the nozzle lower face 11a.

The discharge aperture 12a, the suction apertures 13a, and the discharge apertures 14a each are made in a slit configuration extending in the Y direction substantially parallel to each other. One discharge aperture 12a is positioned at nearly the center in the X direction. A pair of suction apertures 13a is positioned on either side of the discharge aperture 12a. The pair of discharge apertures 14a is positioned on either side of the pair of suction apertures 13a.

The discharge path 12, the suction paths 13, and the discharge paths 14 are connected to a supply pipe of the cleaning fluid, a suction exhaust pipe, and a supply pipe of the rinsing fluid, respectively, at the nozzle upper face side. The suction paths 13 are connected also to a discharge system that discharges used cleaning fluid and rinsing fluid.

The nozzle 11 is movable relative to the mask substrate in a state in which the lower face 11a faces the surface to be cleaned (processing surface) of the mask substrate. For example, in this embodiment, the mask substrate is in a fixed position while the nozzle 11 is movable in a straight line in the X direction by a not-illustrated movement mechanism.

The nozzle 11 and the mask substrate may be movable relative to each other; a configuration may be used in which the mask substrate is moved with respect to the fixed nozzle 11; or a configuration may be used in which both the nozzle 11 and the mask substrate may include movable mechanisms. Further, “move” is not limited to straight-line movement and includes rotational movement.

The nozzle lower face 11a, that is, the discharge aperture 12a, the suction apertures 13a, and the discharge apertures 14a, face the processing surface of the mask substrate and are separated therefrom by a gap of, for example, about 100 μm.

In this state, the cleaning fluid is discharged toward the processing surface from the discharge aperture 12a. Simultaneously, suction is applied through the suction apertures 13a. Therefore, the cleaning fluid supplied onto the processing surface forms a flow on the processing surface toward the suction apertures 13a, and is suctioned into a suction aperture 13a upon reaching a position below the suction aperture 13a. Accordingly, the supply area of the cleaning fluid is limited to a region on the inner side of the pair of suction apertures 13 (the region enclosed by a thick line 15 in FIG. 6).

The cleaning fluid is successively supplied from the discharge aperture 12a onto the processing surface and is suctioned into a suction aperture 13a immediately after flowing a distance corresponding to the distance between the discharge aperture 12a and the suction aperture 13a. Therefore, the cleaning fluid supply area (the region enclosed by the thick line 15 in FIG. 6) can be constantly filled by fresh cleaning fluid.

Simultaneous to the discharge and suction operations of the cleaning fluid recited above, a rinsing fluid is discharged from the discharge apertures 14a. The rinsing fluid is, for example, purified water. The rinsing fluid does not affect the transmittance, phase difference, configuration, and the like of the film on the mask substrate, and can be supplied onto the entire processing surface without problems regardless of the possible cleaning number distribution.

Although the flow which is discharged from a discharge aperture 14a onto the processing surface toward a suction aperture 13a is suctioned into the suction aperture 13a, the flow of the rinsing fluid flows in opposition to the flow of the cleaning fluid discharged from the discharge aperture 12a toward the suction aperture 13a, and therefore inhibits the cleaning fluid from flowing outside of the region enclosed by the thick line 15 recited above; and the selective supply of the cleaning fluid can be reliably performed.

When performing a selective cleaning of a mask substrate using the nozzle 11 recited above, first, the rinsing fluid is supplied onto the processing surface, and then the nozzle 11 is moved to the desired position.

For example, in the example illustrated in FIG. 7, first, the nozzle 11 is moved to a position facing a region 17a illustrated by solid diagonal lines. The dimension of the nozzle 11 in the longitudinal direction (Y direction) has a length, for example, that can cover the square mask substrate 10 in the direction of a side a1. The discharge aperture 12a, the suction apertures 13a, and the discharge apertures 14a described above face the processing surface with the longitudinal directions (Y direction) thereof substantially parallel to the side a1 direction.

Then, by performing suction while discharging the cleaning fluid as described above, only the region 17a is selectively cleaned; and the particle 2 in the region 17a is removed. The region 17a does not overlay the region 10a in which cleaning is not permissible; and only the region 17a is selectively cleaned; and therefore, the cleaning fluid is not undesirably supplied to the region 10a.

After cleaning the region 17a, first, the discharging operation of the cleaning fluid is stopped; then, the suction operation is stopped; and the nozzle 11 is moved to the next region to be cleaned 17b. In the case where the suction operation is stopped prior to stopping the discharging operation, the cleaning fluid is not suctioned and undesirably spreads outside of the region 17a. Therefore, the discharge of the cleaning fluid is stopped first; and then the suction operation is stopped.

A cleaning processing similar to that described above is performed for the region 17b, and the particles 2 positioned in the region 17b are removed.

After stopping the discharge of the cleaning fluid and stopping the suction operation, the discharge of the rinsing fluid is stopped; and finally, the rinsing fluid on the processing surface is dried, and the cleaning processing ends.

In the case where the width of the region to be cleaned in the direction of a side a2 (the direction substantially perpendicular to the side a1 direction recited above) is wider than the lateral direction (X direction) of the nozzle 11, the nozzle 11 is moved in the X direction while performing the discharge and suction operations of the cleaning fluid and the rinsing fluid to cover the area in the side a2 direction recited above.

In the case where the cleaning described above is the first cleaning, and in the case where, for example, a particle 2a illustrated in the lower right of FIG. 7 is not removed by the first cleaning, the particle 2a is in the region 10c in which two cleanings are possible; and therefore, a second cleaning attempts to remove the particle 2a. At this time, cleaning fluid is not supplied to the region 10a in which cleaning is not permissible, nor to regions in the region 10b for which the first cleaning processing was performed and for which only one cleaning is possible (the regions where the regions 17a and 17b overlay the region 10b in FIG. 7).

Based on the positional relationship between the nozzle 11 and the mask substrate 10 when performing the cleaning of the regions 17a and 17b recited above, the nozzle 11 is, for example, rotated 90° (or the mask substrate 10 is rotated 90°), and the nozzle lower face 11a is positioned to face a region 17c illustrated by the single dot-dash diagonal line in FIG. 7. The region 17c includes the particle 2a still remaining on the processing surface and is in the region 10c in which two cleanings are possible. Therefore, the particle 2a can be removed by the cleaning processing of the region 17c.

Conventionally, the cleaning processing is performed on the entire processing surface, undesirably resulting in damage to the entire processing surface due to cleaning; a region occurs in the mask surface in which the desired transmittance, phase difference, pattern configuration, and the like prescribed to ensure the desired lithographical likelihoods are out of specification; and the yield decreases during mask manufacturing.

Conversely, in this embodiment, only the necessary region near the position at which the particle is adhered is selectively cleaned. Thereby, changes of the transmittance and/or phase difference of the exposure light, the dimensions of the formed pattern, etc., due to cleaning may be considered only in the cleaned region. Therefore, limitations are drastically reduced when performing the determination of whether or not it is possible to clean and remove a particle. Thereby, it becomes possible to clean and remove a particle at a position that conventionally could not be cleaned and removed due to limitations on the number of possible cleanings; and the yield during mask manufacturing can be improved.

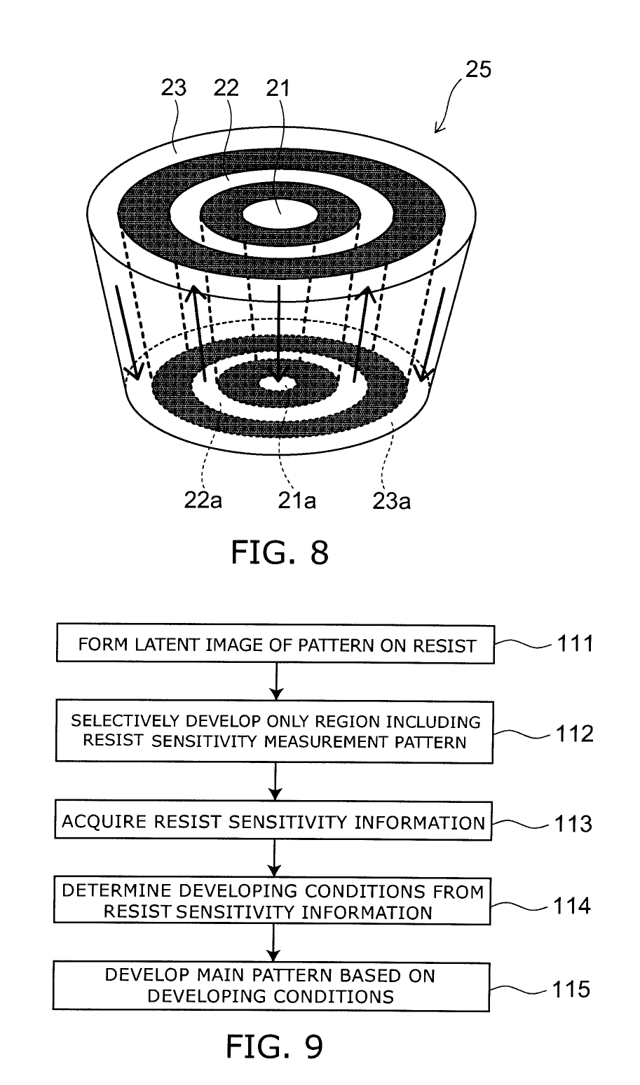

The nozzle performing the selective supply of the cleaning fluid is not limited to that illustrated in FIGS. 5 and 6. For example, a nozzle 25 illustrated in FIG. 8 may be used.

The nozzle 25 includes a triple tubular structure that includes, in order from the center, a discharge path 21 and a suction path 22 of the cleaning fluid and a discharge path 23 of the rinsing fluid made in a concentric-circular configuration. On a lower face thereof, a discharge aperture 21a, a suction aperture 22a, and a discharge aperture 23a are opened to communicate with the discharge path 21, the suction path 22, and the discharge path 23, respectively.

The nozzle 25 also is movable relative to the mask substrate in a state in which the discharge aperture 21a, the suction aperture 22a, and the discharge aperture 23a face the processing surface.

Cleaning fluid is discharged from the discharge aperture 21a toward the processing surface. Simultaneously, suction is performed through the suction aperture 22a which encloses the discharge aperture 21a from the outside. Therefore, the cleaning fluid supplied onto the processing surface forms a flow on the processing surface toward the suction aperture 22a, and is suctioned into the suction aperture 22a upon reaching a position below the suction aperture 22a. Accordingly, the supply area of the cleaning fluid is limited to a region inside the suction aperture 22a.

Simultaneous to the discharge and suction operations of the cleaning fluid recited above, rinsing fluid is discharged from the discharge aperture 23a enclosing the suction aperture 22a from the outside. Although the flow discharged from the discharge aperture 23a onto the processing surface toward the suction aperture 22a is suctioned through the suction aperture 22a, the flow of the rinsing fluid flows in opposition to the flow of the cleaning fluid discharged from the discharge aperture 21a toward the suction aperture 22a, and therefore inhibits the cleaning fluid from flowing into a region outside of the suction aperture 22a; and the selective supply of the cleaning fluid can be reliably performed.

Further, the nozzle 25 allows the supply of cleaning fluid in a circular spot. Therefore, it is possible to selectively process a region smaller than that by the nozzle 11 illustrated in FIGS. 5 and 6. Thereby, undesirable diffusion of the cleaning fluid into other regions can be inhibited even more, and limiting conditions are further reduced when determining whether or not a particle can be cleaned.

For the nozzles 11 and 25 described above, the rinsing fluid may not always be discharged. By adjusting in advance the balance of discharge parameters (pressure and flow rate) and the suction parameters (pressure and flow rate) of the cleaning fluid, the cleaning fluid can be prevented from flowing outside of the suction aperture; and it is possible to realize a selective cleaning of only the necessary region. However, as described above, a selective cleaning can be performed more reliably by inhibiting the flow of the cleaning fluid outward by the flow of the rinsing fluid toward the suction aperture. Further, it is favorable to supply the rinsing fluid evenly in advance onto the processing surface, provide a state in which only the rinsing fluid evenly remains on the processing surface after the cleaning processing, and then perform a drying in that state.

### Second Embodiment

The developing processing of a resist formed on a mask substrate will now be described as an example of a substrate processing method according to a second embodiment of the present invention.

FIG. 9 is a flowchart illustrating main processes of the mask manufacturing including a developing method according to this embodiment.

First, in step 111, a latent image of a pattern is formed on a resist by, for example, applying the resist on a mask substrate including a light shielding film and/or a semi-transparent film on a glass substrate; exposing the pattern in the resist (for example, by electron-beam lithography); and then performing PEB (Post Exposure Baking).

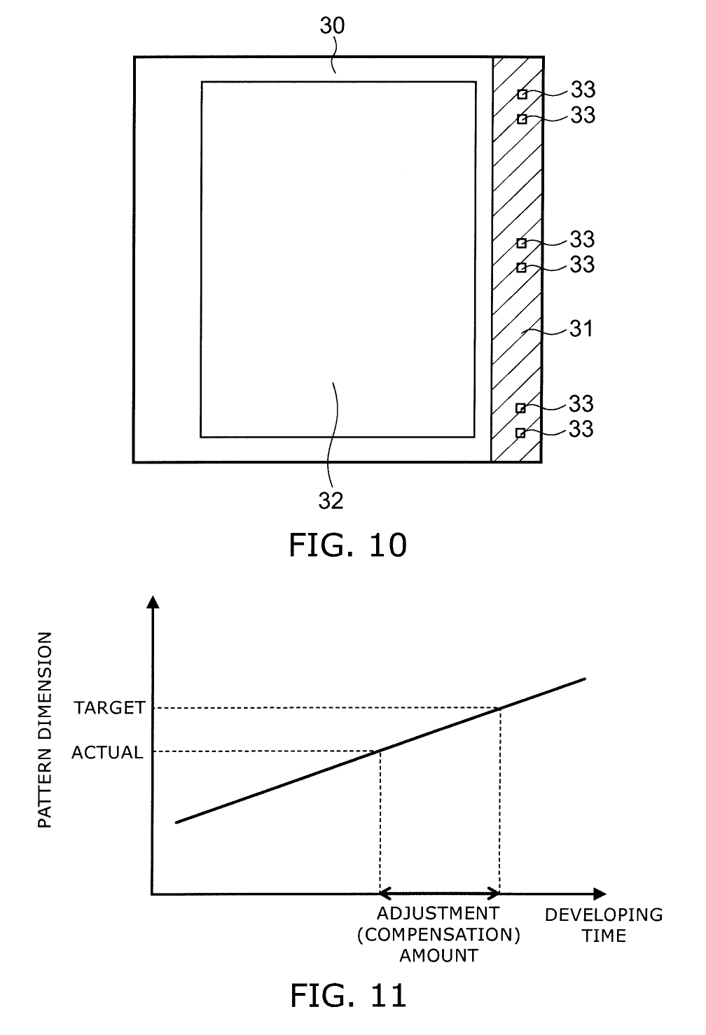

FIG. 10 illustrates a resist formation surface of a mask substrate 30 to be processed in this embodiment. The resist surface can be largely divided into a formation region 32 of the main pattern and a formation region 31 of resist sensitivity measurement patterns 33.

The main pattern corresponds to a semiconductor integrated circuit pattern actually transferred to a semiconductor wafer. The resist sensitivity measurement patterns 33 are outside of the main pattern formation region 32 and are formed on an end portion of the mask substrate 30.

When developing the pattern latent image in this embodiment, first, only the region 31 including the resist sensitivity measurement patterns 33 is selectively developed (step 112). When selectively developing only the region 31, the nozzle 11 described above is used.

In other words, a developing fluid is discharged from the discharge aperture 12a toward the processing surface in a state in which the nozzle lower face 11a faces the region 31. Suction through the suction apertures 13a is performed simultaneously. Therefore, the developing fluid supplied onto the processing surface forms a flow on the processing surface toward a suction aperture 13a, and is suctioned into the suction aperture 13a upon reaching a position below the suction aperture 13a. Accordingly, the supply area of the developing fluid is limited to a region on the inner side of the pair of suction apertures 13a (the region enclosed by the thick line 15 in FIG. 6); and the developing fluid is not supplied to the main pattern formation region 32.

The resist sensitivity measurement patterns 33 are formed by the selective developing processing of the region 31.

In the next step, parameters relating to dissolution characteristics of the resist such as dimensions and the film thickness are measured for the resist sensitivity measurement patterns 33 after developing processing. Resist sensitivity information (for example, pattern dimensions, dissolution rate, etc.) is calculated from the measured data (step 113).

Then, in step 114, developing conditions for finishing the main pattern to the desired dimensions are ascertained from the obtained resist sensitivity information recited above. Specifically, as illustrated in FIG. 11, the correlation between developing conditions (for example, the developing time) and the target value of the pattern dimensions are obtained in advance; and the adjustment (compensation) amount of the developing time is calculated from the dimensions of the resist sensitivity measurement patterns 33 recited above obtained by the actual developing processing.

The developing processing of the main pattern formation region 32 is performed based on the developing conditions thus obtained (step 115). Thereby, the dimensional precision of the resist pattern for forming the main pattern can be improved. As a result, the dimensional precision of the main pattern obtained by performing etching of the light shielding film and/or the semi-transparent film using the resist as a mask can be improved, and the yield during the mask manufacturing can be improved.

In particular, a chemical amplification resist includes multiple components such as a base polymer, an acid generator, a quencher, a solvent, and the like. Currently, it is difficult to retain reproducibility of the same sensitivity even when manufactured with the components mixed in exactly the same proportions; and as a result, the pattern dimensions are undesirably different for each mask substrate.

Also, methods for monitoring the sensitivity of the resist are not established. Therefore, it is not possible to know the sensitivity in advance until the resist is actually applied to the substrate, exposed, baked, developed, and actually formed into a resist pattern. In a conventional method to obtain the resist sensitivity, which is an unknown parameter until actually developed, one mask substrate is processed in advance and data is obtained relating to the resist sensitivity from the substrate; and then the data is used as feedback for the processing conditions of the following processing lots. In such a case, it is necessary to measure the sensitivity each time the resist lot changes; and the sacrifice of a substrate, especially a high-cost substrate such as a photomask, merely to obtain the resist sensitivity results in costly waste.

Conversely, in this embodiment, the resist sensitivity measurement patterns 33 are formed separately from the main pattern on the same mask substrate 30 by performing the selective developing processing described above. Thereby, information related to the sensitivity of the resist applied on the substrate can be obtained prior to developing the main pattern; practical use for actual products is possible without wasting an expensive mask substrate; and costs can be reduced.

### Third Embodiment

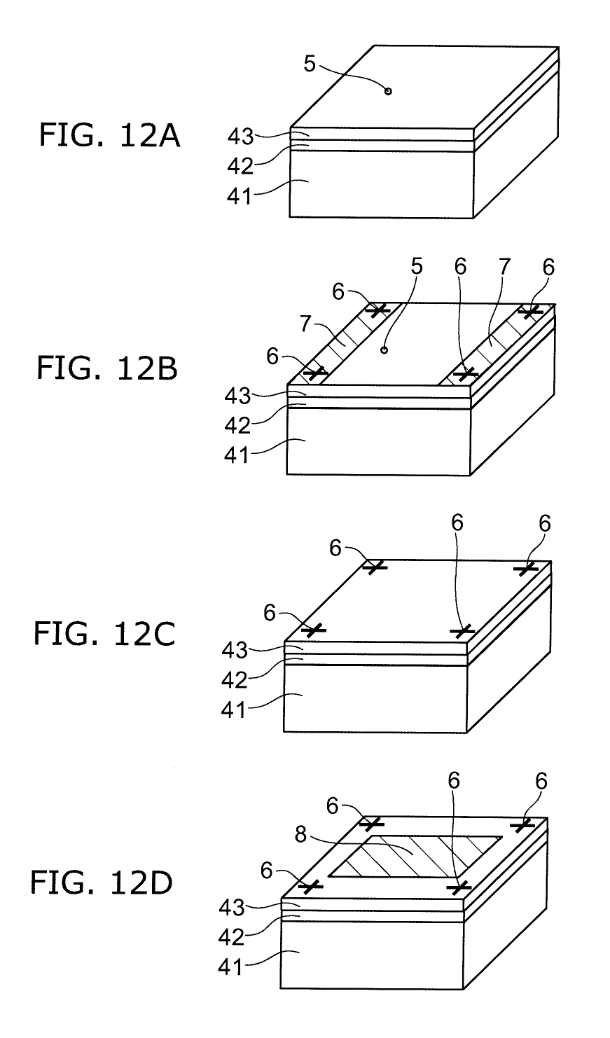

Selective developing processing of a resist 43 illustrated in FIGS. 12A to 12D will now be described as an example of a substrate processing method according to a third embodiment of the present invention.

FIG. 12A illustrates a mask substrate in which a light shielding film (or transparent film) 42 is formed on a glass substrate 41 and a resist 43 is formed thereabove. Pattern lithography is not yet performed on the resist 43. A particle 5 is adhered on the resist 43 surface.

First, electron-beam lithography and then PEB are performed to form a latent image of pattern marks 6 in, for example, four corners of the resist 43.

Then, similar to the embodiments described above, nozzle 11 is used to perform a selective developing processing of only an end portion region 7 of the resist 43 surface; and the pattern marks 6 are formed. Alternatively, the nozzle 25 illustrated in FIG. 8 may be used during the developing processing.

Subsequently, rotational drying, for example, of the mask substrate is used. Then, the resist 43 surface is optically inspected; the relative coordinates of the particle 5 with respect to the pattern marks 6 is ascertained; and the position of the particle 5 is designated. Then, a jig including, for example, one or multiple needles is used to pick up and remove the particle 5 from the resist 43 while confirming the position of the particle 5 (the relative coordinates with respect to the pattern marks 6) (FIG. 12C). An optical inspection is then once again performed to confirm the removal of the particle.

Continuing, electron-beam lithography, PEB, developing, rinsing, drying, and etching processes are performed on the main pattern formation region 8 illustrated in FIG. 12D to form the desired main pattern.

According to this embodiment, the existence/absence of a particle that may have adhered on the resist surface when transferring the mask substrate to, for example, an SMIF (Standard Mechanical Interface) pod prior to the pattern formation processing is inspected prior to the pattern formation processing. In the case where the adhesion of a particle is confirmed, the pattern marks 6 are formed by the selective developing processing described above. Then, the pattern marks 6 can be used as a reference to designate the position coordinates of the particle 5. Therefore, the particle 5 can be picked up and removed by pinpoint. Then, the main pattern can be formed in a state in which no particle is adhered; and the yield can be improved.

The number and configuration of the needles used to pick up the particle is not limited. Any configuration that can pick up and remove the particle may be used. It is possible to provide an electrostatic mechanism on the needle to increase the reliability (efficiency) of the particle removal.

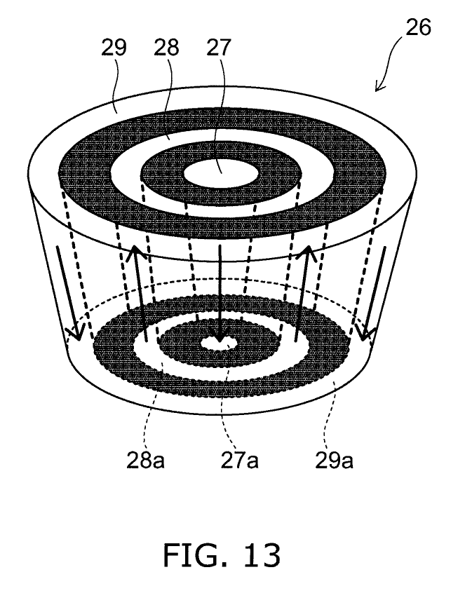

Alternatively, an air nozzle 26 illustrated in FIG. 13 may be used to remove the particle from the resist surface.

The nozzle 26 includes a triple tubular structure that includes, in order from the center, an air jet path 27, an air suction path 28, and an air jet path 29 made in a concentric-circular configuration. On a lower face thereof, an air jet aperture 27a, an air suction aperture 28a, and an air jet aperture 29a are opened to communicate with the air jet path 27, the air suction path 28, and the air jet path 29, respectively.

A suction operation is performed through the air suction aperture 28a while simultaneously shooting air from the air jet apertures 27a and 29a. The particle can be removed from the resist surface by blowing air around the particle from the air jet aperture 27a, causing the particle to lift from the resist surface, and suctioning the particle through the suction aperture 28a. Here, air is also shot from the jet aperture 29a which encloses the suction aperture 28a. Therefore, a particle that is projected by the air from the jet aperture 27a at the center can be prevented from scattering outside of the suction aperture 28a and undesirably re-adhering at another position on the resist surface.

### Fourth Embodiment

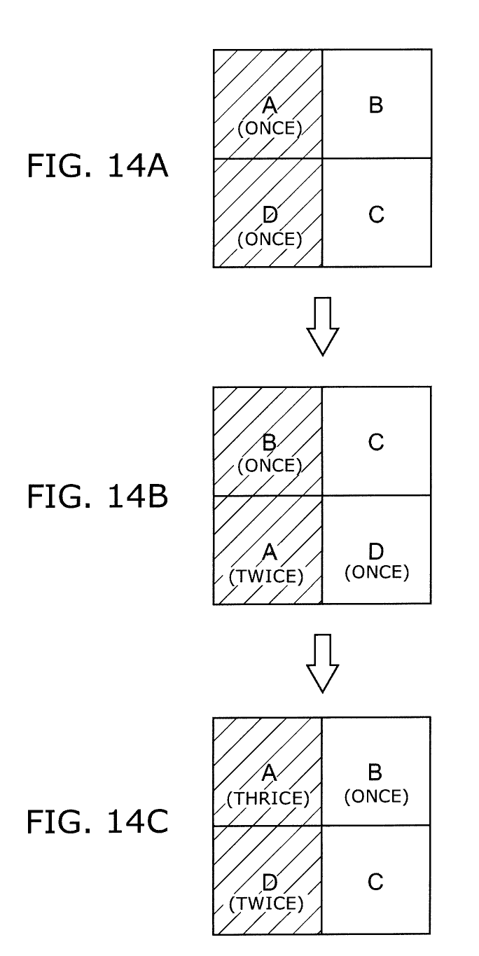

A fourth embodiment of the present invention will now be described with reference to FIG. 14.

A resist of a mask substrate illustrated in FIGS. 14A to 14C is divided into, for example, four regions A to D. The latent image of an evaluation pattern is formed on each of the regions A to D.

First, as illustrated in FIG. 14A, a developing processing is performed to form an evaluation pattern selectively only on the left two regions (the regions A and D) by a selective developing method similar to that of the embodiments described above.

Then, the mask substrate is rotated 90° from the position illustrated in FIG. 14A and positioned as illustrated in FIG. 14B. The selective developing processing is performed to form an evaluation pattern only on the left two regions (the regions A to D).

Continuing, the mask substrate is rotated 90° from the position of FIG. 14B and positioned as illustrated in FIG. 14C (the same position as in FIG. 14A). The selective developing processing is performed to form an evaluation pattern only on the left two regions (the regions A and D).

As a result of the series of selective developing processing described above, the region A undergoes the developing processing thrice, the region D undergoes the developing processing twice, and the region B undergoes the developing processing once. By using the same developing processing time for each processing, the developing time of the region A is the longest; the developing time of the region B is the shortest; and the developing time of the region D is a developing time between those of the regions A and B.

In other words, in this embodiment, the evaluation of three different processing conditions (developing times) can be performed on the same mask substrate by performing the selective developing processing described above multiple times (three times in the example recited above); and costs can be drastically reduced in comparison to the case in which three mask substrates having different developing times are processed and evaluated.

### Fifth Embodiment

A substrate processing method according to a fifth embodiment of the present invention will now be described.

In this embodiment, the progress status of the developing of a monitor pattern formed on the same substrate as the main pattern is detected simultaneous to the progress of the developing of the main pattern, and uses the detection result as feedback for the developing processing of the main pattern.

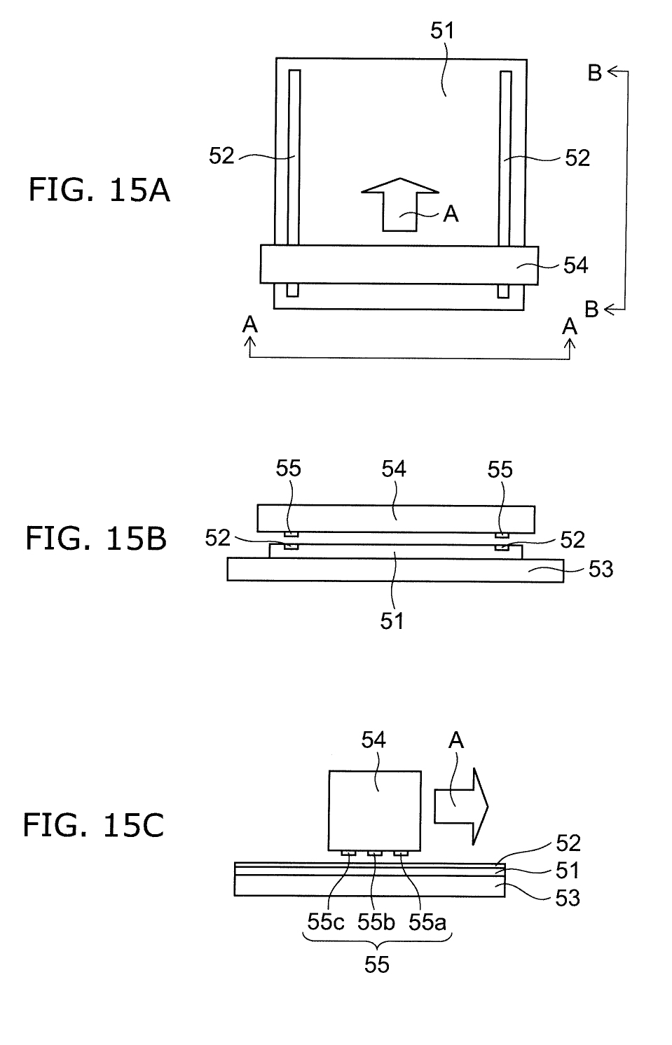

FIGS. 15A to 15C illustrate schematic views of a developing processing apparatus used in this embodiment. FIG. 15A is a top view from a processing surface (resist surface) side of a mask substrate 51. FIG. 15B is a view along the A-A direction of FIG. 15A. FIG. 15C is a view along the B-B direction of FIG. 15A.

The mask substrate 51 is retained substantially horizontally by a substrate retaining mechanism 53. A nozzle 54 is provided facing the mask substrate 51 from above. The mask substrate 51 and the nozzle 54 are movable relative to each other. Although the nozzle 54 moves in an arrow A direction with respect to a stationary mask substrate 51 in the description of this embodiment, a configuration in which the mask substrate 51 moves with respect to a stationary nozzle 54, or a configuration in which both the nozzle 54 and the mask substrate 51 move may be used.

The configuration of the nozzle 54 has a long extension in a direction substantially orthogonal to a movement direction A. Discharge apertures (not illustrated) of developing fluid are made along the longitudinal direction thereof. The discharge apertures of the developing fluid are opened in a nozzle lower face and proximally face the resist surface.

Reflectance measurement mechanisms 55 which include a light source and a light detector are provided on each end portion in the longitudinal direction of the nozzle 54. As illustrated in FIG. 15C, the reflectance measurement mechanisms 55 include three reflectance measurement mechanisms 55a to 55c provided in line along the movement direction of the nozzle 54. A first reflectance measurement mechanism 55a, a second reflectance measurement mechanism 55b, and a third reflectance measurement mechanism 55c are positioned in this order from the arrow A side of the nozzle 54. The number of reflectance measurement mechanisms is not limited to three; and one or four or more may be provided.

A latent image of a monitor pattern 52 is formed on the end portion region outside of the main pattern formation region of the resist surface of the mask substrate 51. The monitor pattern 52 is formed in a line configuration extending along the movement direction A of the nozzle 54 and to face the reflectance measurement mechanisms 55.

In the example illustrated in FIGS. 15A to 15C, the nozzle 54 moves in the arrow A direction while discharging the developing fluid toward the resist surface during the developing processing. At this time, the developing of the monitor pattern 52 is performed with the developing of the main pattern corresponding to the pattern to be actually transferred to a semiconductor wafer.

Then, in this embodiment, the reflectance of the monitor pattern 52 is measured by the reflectance measurement mechanisms 55a to 55c. The reflectance of the monitor pattern 52 changes according to the film thickness of the monitor pattern 52. Accordingly, the degree of the progress of the developing of the monitor pattern 52 can be known by measuring the reflectance of the monitor pattern 52.

FIG. 16 illustrates the relationship between the reflectance (vertical axis) and the developing time (horizontal axis) recited above. A curve a illustrates a target curve to obtain the desired pattern dimensions.

First, the first reflectance measurement mechanism 55a reaches a position x at a time t0, and the second reflectance measurement mechanism 55b reaches the same position x after an elapse Δt1. Then, the reflectance (resist film thickness of the monitor pattern formation location) measured by the second reflectance measurement mechanism 55b at the position x is lower than the reflectance (resist film thickness) measured at the position x by the first reflectance measurement mechanism 55a. Similarly, the third reflectance measurement mechanism 55c reaches the position x after an elapse Δt2 from when the second reflectance measurement mechanism 55b reaches the position x. Then, the reflectance (resist film thickness) measured by the third reflectance measurement mechanism 55c at the position x is lower than the reflectance (resist film thickness) measured at the position x by the second reflectance measurement mechanism 55b.

The progress status of developing the resist can be known from the reflectance difference (resist film thickness difference) measured at the same position on the monitor pattern 52 by the first reflectance measurement mechanism 55a, the second reflectance measurement mechanism 55b, and the third reflectance measurement mechanism 55c.

In this embodiment, in the case where the progress status of the developing is faster (curve c) or slower (curve b) than the target curve a, the developing conditions are provided as feedback to obtain the target curve a.

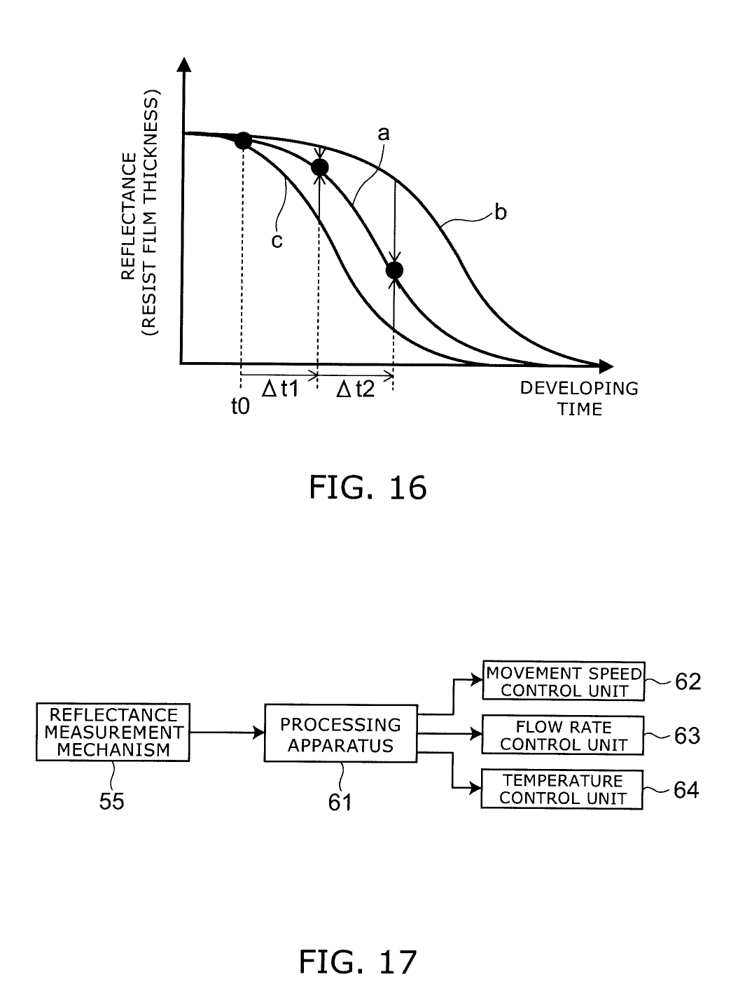

Specifically, the developing progress information obtained by the measurements of the reflectance measurement mechanisms 55 is output to a processing apparatus 61 illustrated in FIG. 17. To obtain the target curve a recited above based on the developing progress information, the processing apparatus 61 adjusts developing conditions such as the movement speed of the nozzle 54 (the speed relative to the substrate 51), the discharge flow rate of the developing fluid, the temperature of the developing fluid, and the like and outputs adjustment amounts (control amounts) of the movement speed, the developing fluid flow rate, and the developing fluid temperature to a movement speed control unit 62, a flow rate control unit 63, and a temperature control unit 64. Based on this data, the movement speed of the nozzle 54, the discharge flow rate of the developing fluid, the temperature of the developing fluid, and the like are controlled; and the developing of the main pattern is performed based on these controls.

In other words, during developing processing in this embodiment, the developing of a monitor pattern formed on the same mask substrate is also performed when developing the main pattern; and developing conditions are adjusted based on developing progress information thereof while acquiring the developing progress information. Therefore, even in the case where the sensitivity of the resist material or the state of the exposure apparatus changes, the developing conditions can be adjusted by responding in real time; the main pattern can be finished to the desired dimensions; and it is possible to achieve the dimensional precision level of several nanometers required in recent years. Further, it is unnecessary to allot a dedicated expensive mask substrate to obtain the adjustment amounts (control amounts) of the developing conditions; and costs can be reduced.

Hereinabove, the embodiments of the present invention are described with reference to specific examples. However, the present invention is not limited thereto, and various modifications are possible within the technical spirit of the present invention.

The substrate processing method of the present invention is not limited to the manufacture of a photomask, and may be applied also to a process for forming a pattern onto a semiconductor wafer, or a pattern formation in a color filter formation process or a fabrication process of a recording medium having a disk configuration.

Moreover, the discharge aperture of the rinsing fluid of the nozzles 11 and 25 described above may not be provided separately. A structure may be used in which the discharge from the central discharge aperture can be switched between the processing fluid (the cleaning fluid or the developing fluid) and the rinsing fluid; the discharge of the processing fluid from the discharge aperture can be stopped after the processing is ended; and the rinsing fluid can be discharged instead of the processing fluid.

1. A substrate processing method that uses a processing fluid to selectively process only a region of a portion of a processing surface of a substrate to be processed, by causing a discharge aperture and a suction aperture of a nozzle having the discharge aperture and the suction aperture for the processing fluid and provided movable relative to the substrate to be processed to face the processing surface of the substrate and suctioning the processing fluid supplied onto the processing surface through the suction aperture while supplying the processing fluid from the discharge aperture onto the processing surface.

2. The method according to claim 1, comprising:
determining an inspection of whether or not an object to be removed exists on the processing surface, and designating a position of the object to be removed in the case where the object to be removed exists on the processing surface;
determining whether or not the position of the object to be removed is in a cleanable region; and
using the nozzle and the processing fluid to selectively clean the cleanable region where the object to be removed is positioned in the case where the position of the object to be removed is in the cleanable region.

3. The method according to claim 2, wherein the determining whether or not the position of the object to be removed is in a cleanable region performs the determination based on a change due to a cleaning of at least one of a transmittance of transmitted light, a phase difference of transmitted light, and a pattern dimension formed on the substrate in the substrate region including the position of the object to be removed.

4. The method according to claim 3, including acquiring change amount data of at least one of the transmittance, the phase difference, and the pattern dimension for one processing in advance, and ascertaining a distribution of a number of possible cleanings of the substrate to obtain a desired lithographical margin based on the change amount data.

5. The method according to claim 4, wherein the position of the object to be removed and the distribution of the number of possible cleanings are compared to determine whether or not the position of the object to be removed is in the cleanable region.

6. The method according to claim 1, wherein a suction operation is stopped after a discharge operation of the processing fluid is stopped.

7. The method according to claim 1, wherein
a rinsing fluid is discharged onto the processing surface simultaneous to a discharge operation and a suction operation of the processing fluid, and
a flow of the rinsing fluid on the processing surface flows in opposition to a flow of the processing fluid discharged from the discharge aperture toward the suction aperture.

8. The method according to claim 1, wherein
the discharge aperture and the suction aperture are made in substantially parallel slit configurations, and
a pair of the suction apertures is provided on either side of the discharge aperture.

9. The method according to claim 1, wherein the nozzle has a tubular structure in which the suction aperture encloses the discharge aperture in a concentric-circular configuration.

10. A mask manufacturing method comprising:
forming a pattern on a mask substrate; and
using a cleaning fluid to selectively clean only a region of a portion of a pattern formation surface of the mask substrate, by causing a discharge aperture and a suction aperture of a nozzle having the discharge aperture and the suction aperture for the cleaning fluid and provided movable relative to the mask substrate to face the pattern formation surface of the mask substrate and suctioning the cleaning fluid supplied onto the pattern formation surface through the suction aperture while supplying the cleaning fluid from the discharge aperture onto the pattern formation surface.

11. The method according to claim 10, comprising:
determining an inspection of whether or not an object to be removed exists on the pattern formation surface, and designating a position of the object to be removed in the case where the object to be removed exists on the pattern formation surface;
determining whether or not the position of the object to be removed is in a cleanable region; and
using the nozzle and the processing fluid to selectively clean the cleanable region where the object to be removed is positioned in the case where the position of the object to be removed is in the cleanable region.

12. The method according to claim 11, wherein the determining whether or not the position of the object to be removed is in a cleanable region performs the determination based on a change due to a cleaning of at least one of a transmittance of transmitted light, a phase difference of transmitted light, and a pattern dimension formed on the substrate in the mask substrate region including the position of the object to be removed.

13. The method according to claim 12, including acquiring change amount data of at least one of the transmittance, the phase difference, and the pattern dimension for one processing in advance, and ascertaining a distribution of a number of possible cleanings of the substrate to obtain a desired lithographical margin based on the change amount data.

14. The method according to claim 13, wherein the position of the object to be removed and the distribution of the number of possible cleanings are compared to determine whether or not the position of the object to be removed is in the cleanable region.

15. The method according to claim 10, wherein a suction operation is stopped after a discharge operation of the cleaning fluid is stopped.

16. The method according to claim 10, wherein
a rinsing fluid is discharged onto the pattern formation surface simultaneous to a discharge operation and a suction operation of the cleaning fluid, and
a flow of the rinsing fluid on the pattern formation surface flows in opposition to a flow of the cleaning fluid discharged from the discharge aperture toward the suction aperture.

17. The method according to claim 10, wherein
the discharge aperture and the suction aperture are made in substantially parallel slit configurations, and
a pair of the suction apertures is provided on either side of the discharge aperture.

18. The method according to claim 10, wherein the nozzle has a tubular structure in which the suction aperture encloses the discharge aperture in a concentric-circular configuration.

19. A mask manufacturing method comprising:
forming a latent image of a pattern on a resist formed on a mask substrate;
developing a latent image formed in a region of a portion of the resist to form a resist sensitivity measurement pattern, by causing a discharge aperture and a suction aperture of a nozzle having the discharge aperture and the suction aperture for a developing fluid and provided movable relative to the mask substrate to face the resist and suctioning the developing fluid supplied onto the region of the portion of the resist through the suction aperture while supplying the developing fluid from the discharge aperture onto the resist;
determining a developing condition from resist sensitivity information obtained during the developing of the resist sensitivity measurement pattern; and
developing a latent image formed on the resist in a region different than the region in which the resist sensitivity measurement pattern is formed based on the developing condition to form a main pattern.

20. The method according to claim 19, wherein the resist sensitivity measurement pattern is formed on an end portion of the mask substrate outside of the main pattern formation region.
